(19) United States
(12) Patent Application Publication
(10) Pub. No.: US 2026/0052672 A1
(43) Pub. Date: Feb. 19, 2026

(54) METHOD FOR MANUFACTURING SEMICONDUCTOR STRUCTURE AND SEMICONDUCTOR STRUCTURE

(71) Applicant: CXMT Corporation, Hefei City (CN)

(72) Inventors: Baorun WU, Hefei City (CN); Zhongming LIU, Hefei City (CN)

(73) Assignee: CXMT Corporation, Hefei City (CN)

(21) Appl. No.: 19/369,264

(22) Filed: Oct. 26, 2025

Related U.S. Application Data
(63) Continuation of application No. PCT/CN2025/078472, filed on Feb. 21, 2025.

(30) Foreign Application Priority Data
May 22, 2024 (CN) 202410653075.3

(51) Int. Cl. H10B 12/00; H01L 21/02; H10D 1/68

(52) U.S. Cl. CPC H10B 12/30; H10B 12/03; H10D 1/714; H10P 14/6309

(57) ABSTRACT

A method for manufacturing a semiconductor structure and a semiconductor structure are disclosed. The method includes the steps as follows. A substrate is provided, where the substrate includes a first region and a second region. A stacked structure with multiple first material layers and multiple second material layers alternately stacked is formed on the first region. First etching is performed to form a groove at one end of the stacked structure, the second region being exposed at the bottom of the groove. Second etching is performed, to remove a part of the multiple second material layers through the groove, and retain the multiple first material layers arranged at intervals. Before the second etching is performed, the method further includes the step as follows. A protective layer is formed on a surface of the second region, where the protective layer further extends toward at least a surface of the first region.

### CROSS-REFERENCE TO RELATED APPLICATIONS

This application is a continuation of International Patent Application No. PCT/CN2025/078472, filed on Feb. 21, 2025, which claims priority to Chinese Patent Application No. 202410653075.3, filed on May 22, 2024. The disclosures of the above-referenced applications are hereby incorporated by reference in their entirety.

### BACKGROUND

In the development of dynamic random access memories (DRAM), performance indexes such as high speed, high integration density, and low power consumption are pursued. With the dimensional miniaturization of semiconductor device structures, existing structures encounter increasingly apparent technological barriers. Therefore, developing more novel structures based on existing structures is a favorable means to break down existing technological barriers.

A three-dimensional dynamic random access memory (3D DRAM), especially a 3D DRAM including a multilayer horizontal cell (MHC), usually includes multiple transistors stacked on a substrate, which meets the above-mentioned requirements.

However, manufacturing processes for multilayer stacked transistors and capacitors are complicated. Especially in the process of manufacturing capacitors, there is high difficulty in etching and filling processes. Therefore, the process flow needs to be optimized urgently, and the device yield also needs to be improved urgently.

### SUMMARY

Embodiments of the present disclosure relate to the field of semiconductor technologies, and in particular, to a method for manufacturing a semiconductor structure and a semiconductor structure.

According to a first aspect of embodiments of the present disclosure, a method for manufacturing a semiconductor structure is provided, including the steps as follows. A substrate is provided, where the substrate includes a first region and a second region. A stacked structure with multiple first material layers and multiple second material layers alternately stacked is formed on the first region. First etching is performed to form a groove at one end of the stacked structure, the second region being exposed at the bottom of the groove. Second etching is performed, to remove a part of the multiple second material layers through the groove, and retain the multiple first material layers arranged at intervals. Before the second etching is performed, the method further includes the step as follows. A protective layer is formed on a surface of the second region, where the protective layer further extends toward at least a surface of the first region.

According to a second aspect of the embodiments of the present disclosure, a semiconductor structure is provided, including: a substrate, where the substrate includes a first region and a second region; a stacked structure located on the first region; a trench structure located at one end of the stacked structure and located on the second region; and a protective layer located on a surface of the second region and at the bottom of the trench structure, and further extending toward at least a surface of the first region.

### BRIEF DESCRIPTION OF DRAWINGS

FIG. 1 is a schematic diagram of providing a substrate according to an example embodiment;

FIG. 2 is a schematic diagram of forming a stacked structure according to an example embodiment;

FIG. 3 is a schematic diagram of forming a groove according to an example embodiment;

FIG. 4 is a schematic diagram of forming a barrier layer on a sidewall of a groove according to an example embodiment;

FIG. 5 is a schematic diagram of forming a protective layer according to an example embodiment;

FIG. 6 is a schematic diagram of removing a barrier layer according to an example embodiment;

FIG. 7 is a schematic diagram of removing a part of second material layers through a groove according to an example embodiment;

FIG. 8 is a schematic diagram of forming capacitor contact structures according to an example embodiment;

FIG. 9 is a schematic diagram of forming capacitor structures according to an example embodiment;

FIG. 10 is a schematic diagram of forming a protective layer according to another example embodiment;

FIG. 11 is a schematic diagram of forming a stacked structure according to another example embodiment;

FIG. 12 is a schematic diagram of forming a groove according to another example embodiment;

FIG. 13 is a schematic diagram of removing a part of second material layers through a groove according to another example embodiment;

FIG. 14 is a schematic diagram of forming capacitor contact structures according to another example embodiment;

FIG. 15 is a schematic diagram of forming capacitor structures according to another example embodiment;

FIG. 16 is a schematic cross-sectional view, which is taken along line A-A', of forming capacitor structures according to another example embodiment;

FIG. 17A is a schematic diagram of forming a 3D DRAM according to an example embodiment; and

FIG. 17B is a schematic diagram of forming a 3D DRAM according to another example embodiment.

### DESCRIPTION OF EMBODIMENTS

The technical solutions of the present disclosure are further described below in detail with reference to the accompanying drawings and the embodiments. Although example implementation methods of the present disclosure are shown in the accompanying drawings, it should be understood that the present disclosure may be implemented in various forms without being limited by the implementations described herein. Instead, these implementations are provided to develop a more thorough understanding of the present disclosure and to fully convey the scope of the present disclosure to a person skilled in the art.

In the following paragraphs, the present disclosure is described more specifically by way of example with reference to the accompanying drawings. The advantages and features of the present disclosure will be clearer from the following description and claims. It should be noted that the accompanying drawings are presented in a highly simplified form and are not drawn to exact scale, and are merely intended to conveniently and clearly assist in describing the embodiments of the present disclosure.

It may be understood that meanings of "on", "over", and "above" in the present disclosure should be understood in the broadest sense, so that "on" means that it is "on" something with no intermediate feature or layer (that is, directly on something), and further includes the meaning that it is "on" something with an intermediate feature or layer.

In the embodiments of the present disclosure, the terms "first", "second", "third", and the like are intended to distinguish between similar objects but do not necessarily indicate a specific order or sequence.

In the embodiments of the present disclosure, the term "layer" refers to a material part including a region having a thickness. The layer may extend over the whole of a lower or upper structure, or may have a range smaller than the range of the lower or upper structure. In addition, the layer may be a region of a homogeneous or heterogeneous continuous structure whose thickness is less than the thickness of a continuous structure. For example, the layer may be located between the top surface and the bottom surface of the continuous structure, or the layer may be located between any horizontal surface pair at a top surface and a bottom surface of the continuous structure. The layer may extend horizontally, vertically, and/or along an inclined surface. The layer may include multiple sublayers.

It should be noted that the technical solutions described in the embodiments of the present disclosure may be arbitrarily combined when there is no conflict.

In related technologies, in a manufacturing process for a 3D memory structure, a stacked body of sacrificial materials usually needs to be formed first, then the sacrificial materials in the stacked body are removed through lateral etching by forming a hole or a groove in the middle or a side edge of the stacked body, and then a target material is configured for filling as a replacement. However, the inventors of this application have found that to fully expose the sacrificial materials, so as to better control the removal of these sacrificial materials, the hole or the groove previously provided in the middle or the side edge of the stacked body often needs to run through the entire stacked body, and the bottom of the hole or the groove exposes the surface of the substrate. Subsequently, an etching agent enters the hole or the groove, so that while the sacrificial materials on the side edge are etched, the etching agent also partially erodes the substrate to form cavities. The cavities cause instability and uncertainty in a subsequent process flow, e.g., a short circuit problem, a parasitic effect, a conformity problem of upper and lower structures, or may cause structural collapse in a severe case.

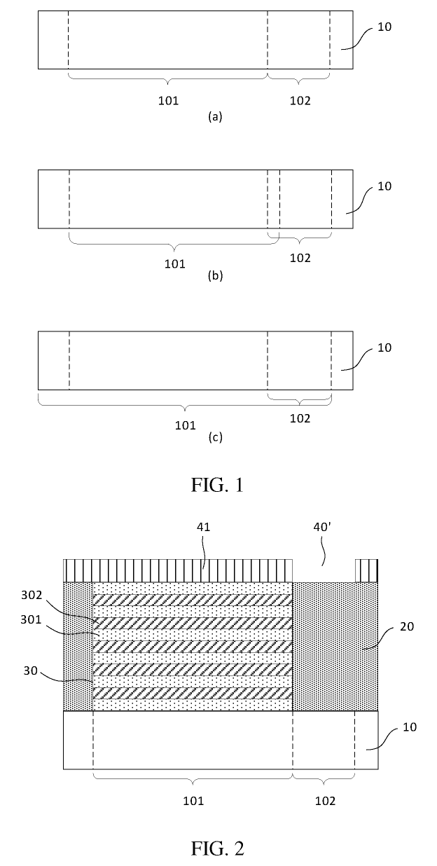

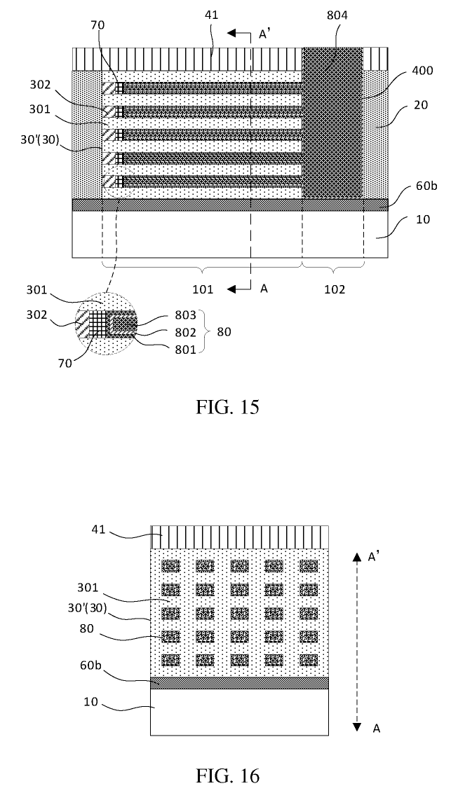

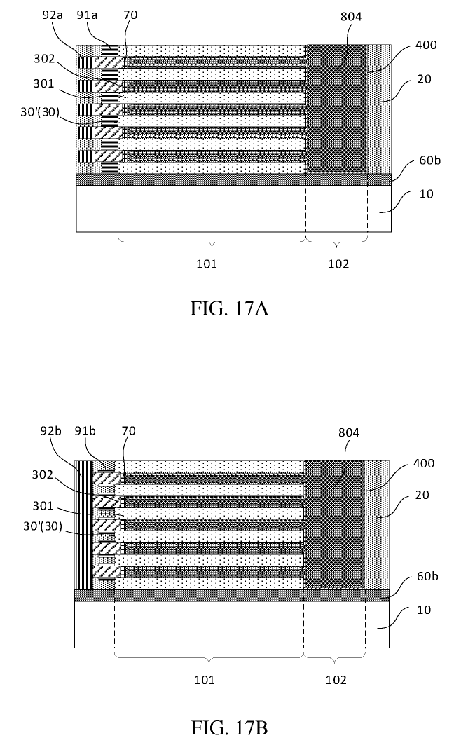

In view of the above technical problems, the present disclosure provides a method for manufacturing a semiconductor structure and a semiconductor structure. The method for manufacturing a semiconductor structure and a semiconductor structure provided by the present disclosure as examples are specifically described below with reference to FIG. 1 to FIG. 17b. FIG. 1 to FIG. 9 are schematic diagrams of steps of a method for manufacturing a semiconductor structure and a structure of the semiconductor structure according to an example embodiment of the present disclosure. FIG. 10 to FIG. 15 are schematic diagrams of steps of a method for manufacturing a semiconductor structure and a structure of the semiconductor structure according to another example embodiment of the present disclosure. FIG. 16 is a schematic cross-sectional view taken along line A-A' of the structure shown in FIG. 15. FIG. 17A and FIG. 17B are schematic structural diagrams of a 3D DRAM according to multiple example embodiments of the present disclosure.

As shown in FIG. 1, a substrate 10 is provided. The substrate 10 includes a first region 101 and a second region 102.

The substrate 10 is provided. The substrate 10 may be made of at least one of the following materials: silicon, germanium, silicon on insulator (SOI), stacked silicon on insulator (SSOI), stacked silicon-germanium on insulator (S-SiGeOI), silicon-germanium on insulator (SiGeOI), germanium on insulator (GeOI), and other semiconductor materials or III-V materials. In an example embodiment of the present disclosure, the substrate 10 is made of monocrystalline silicon.

The substrate 10 includes a first region 101 and a second region 102. In some embodiments, the first region 101 is adjacent to the second region 102, as shown in FIG. 1(a). In some other embodiments, the first region 101 and the second region 102 partially overlap, as shown in FIG. 1(b). In still some other embodiments, the second region 102 is entirely located in the first region 101, as shown in FIG. 1(c). Specific arrangements of the first region 101 and the second region 102 can be determined based on requirements for relative positions of a subsequently formed groove and a stacked structure. In an example embodiment of the present disclosure, the first region 101 is adjacent to the second region 102.

In an example embodiment of the present disclosure, as shown in FIG. 2, a stacked structure 30 with multiple first material layers 301 and multiple second material layers 302 alternately stacked is formed on the first region 101.

The first material layers 301 may be made of at least one or any combination of the following materials: silicon oxide, silicon nitride, silicon oxynitride, silicon carbide, silicon carbonitride, and silicon oxycarbonitride. In an example embodiment of the present disclosure, the first material layers 301 are made of silicon oxide. The second material layers 302 may be made of at least one or any combination of the following materials: silicon, germanium, silicon germanium (SiGe), III-V materials, an indium gallium zinc oxide (IGZO), and a two-dimensional material. In an example embodiment of the present disclosure, the second material layers 302 are made of monocrystalline silicon.

In some embodiments, a stacked structure 30 formed by alternately stacking multiple first material layers 301 and multiple second material layers 302 is formed on the first region 101. In some other embodiments, the stacked structure 30 further extends to a region outside the first region 101.

In some embodiments, the structure located in the same horizontal layer as the second material layers 302 alternatively includes insulating material layers and the second material layers 302 that are alternately arranged. The insulating material layers herein may be made of the same material as the first material layers 301. It can be understood that the second material layers 302 in a single horizontal layer are arranged in parallel and at intervals in a strip shape.

In some embodiments, a bottom layer of the stacked structure 30, namely a layer, which is in direct contact with the substrate 10, of the stacked structure 30 is a first material layer 301, to ensure isolation of a subsequently formed capacitor structure or memory cell from the substrate 10. In some embodiments, a top layer of the stacked structure 30, namely a layer, which is farthest from the substrate 10, of the stacked structure 30 is a first material layer 301, to protect the second material layer 302 below the layer and a subsequently formed capacitor structure from possible damage in a subsequent manufacturing process.

In some embodiments, a method for forming a stacked structure 30 includes the steps as follows. An initial stacked structure is first formed on at least a first region 101. Specifically, an initial stacked structure with alternately stacked silicon-silicon germanium (Si-SiGe) is grown on at least the first region 101 by an epitaxial growth method. Then, silicon germanium layers in the initial stacked structure are removed by a method of selective etching. For example, by wet chemical etching with high selectivity, the silicon germanium layer can be sufficiently removed, and silicon layers can be relatively completely retained as second material layers 302. Finally, gaps formed after the removal of the silicon germanium layers are filled with an insulating material as first material layers 301.

In some embodiments, before or after the stacked structure 30 is formed on the first region 101, the method further includes the step as follows. An insulating layer 20 is formed on a region (including at least the second region 102) of the substrate 10 other than the first region 101. The insulating layer 20 is as high as the stacked structure 30.

In some embodiments, after the stacked structure 30 and the insulating layer 20 are formed, the method further includes the step as follows. A mask layer 41 is formed to cover the stacked structure 30 and the insulating layer 20. An opening 40' is formed in the mask layer 41 to expose a top surface of the insulating layer 20 or a part of a top surface of the stacked structure 30. In an example embodiment of the present disclosure, a projection of the opening 40' on the substrate 10 coincides with the second region 102. Specifically, the opening 40' can be formed by a photolithography method to expose a part of the top surface of the insulating layer 20.

In some embodiments, the mask layer 41 may be made of one or a combination of more of a photoresist, a spin-on hardmask (SOH), spin-on carbon (SOC), amorphous carbon, polysilicon, silicon nitride, silicon oxynitride, and silicon carbonitride.

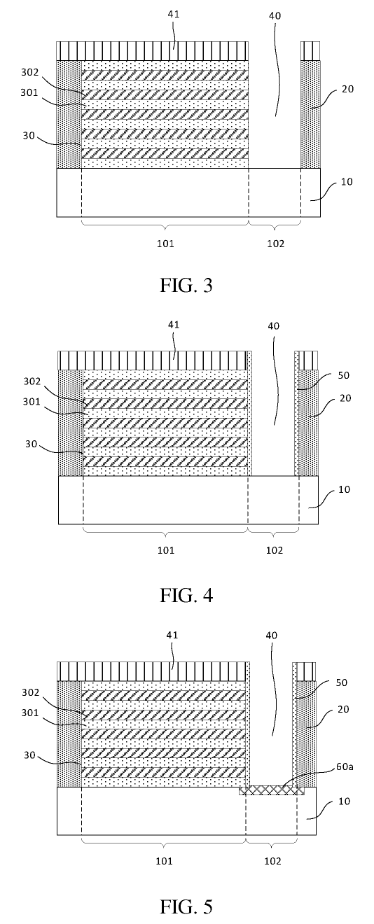

In an example embodiment of the present disclosure, in an example in which the first region 101 is adjacent to the second region 102 (namely in the case of (a) in FIG. 1), after the mask layer 41 with the opening 40' is formed as shown in FIG. 2, referring to FIG. 3, first etching is performed. That is, the insulating layer 20 in contact with one end of the stacked structure 30 is etched through the opening 40' to form a groove 40. A surface of the second region 102 is exposed at the bottom of the groove 40, and at least one end of each of all the second material layers 302 in the stacked structure 30 is exposed from a sidewall of the groove 40.

In another example embodiment of the present disclosure, in an example in which the first region 101 and the second region 102 partially overlap (namely in the case of (b) in FIG. 1), after the mask layer 41 with the opening 40' is formed, the opening 40' further exposes part of the top surface of the stacked structure 30, and first etching is performed. That is, the insulating layer 20 in contact with one end of the stacked structure 30 and the exposed part of the stacked structure 30 are etched through the opening 40' to form a groove 40. A surface of the second region 102 is exposed at the bottom of the groove 40, and at least one end of each of all the second material layers 302 in the stacked structure 30 is exposed from a sidewall of the groove 40.

In still another example embodiment of the present disclosure, in an example in which the second region 102 is entirely located in the first region 101 (namely in the case of (b) in FIG. 1), after the mask layer 41 with the opening 40' is formed, the opening 40' exposes only a part of the top surface of the stacked structure 30, and first etching is performed. That is, the exposed part of the stacked structure 30 is etched through the opening 40' to form a groove 40. A surface of the second region 102 is exposed at the bottom of the groove 40, and at least one end of each of all the second material layers 302 in the stacked structure 30 is exposed by a sidewall of the groove 40.

In some embodiments, an etching method of the first etching may be at least one of the following deposition methods: plasma dry etching, ion beam etching (IBE), and reactive ion etching (RIE).

In some embodiments, after the first etching is performed to form the groove 40, the mask layer 41 is removed. In some other embodiments, the mask layer 41 remains at least at the top of the stacked structure 30.

In an example embodiment of the present disclosure, after the first etching is performed to form the groove 40, as shown in FIG. 4, a barrier layer 50 is formed on the sidewall of the groove 40, with an objective of protecting at least a sidewall of the stacked structure 30 exposed by the groove 40. On the one hand, it is prevented that surfaces of the second material layers 302 in the stacked structure 30 that are adjacent to the groove 40 are oxidized due to exposure in the subsequent process of manufacturing a protective layer, and on the other hand, it is prevented that water vapor may penetrate into only the stacked structure in the air environment, thereby affecting performance of the device structure.

In some embodiments, the barrier layer 50 may be made of at least one or a combination of more of silicon oxide, silicon nitride, silicon oxynitride, and silicon carbonitride. In an example embodiment of the present disclosure, the barrier layer 50 is made of silicon nitride.

In some embodiments, before the barrier layer 50 is formed on the sidewall of the groove 40, a barrier material layer (not shown) is first formed on the substrate 10 to cover the top surface of the insulating layer 20, the top surface of the stacked structure 30, and the sidewall of the groove 40, and then the barrier material layer located on the top surface of the insulating layer 20, the top surface of the stacked structure 30, and a bottom surface of the groove 40 is removed by dry etching, while the barrier material layer located on a side surface of the groove 40 is retained as the barrier layer 50.

In some embodiments, the barrier material layer may be at least one of the following deposition methods: chemical vapor deposition (CVD), low-pressure chemical vapor deposition (LPCVD), plasma enhanced chemical vapor deposition (PECVD), ultra-high vacuum chemical vapor deposition (UHVCVD), flowable chemical vapor deposition (FCVD), direct liquid injection chemical vapor deposition (DLICVD), rapid thermal chemical vapor deposition (RTCVD), microwave plasma assisted chemical vapor deposition (MPCVD), organometallic chemical vapor deposition (MOCVD), and atomic layer deposition (ALD).

In an example embodiment of the present disclosure, after the groove 40 is formed, a protective layer 60a is formed on the surface of the second region 102 exposed at the bottom of the groove 40. As shown in FIG. 5, in some embodiments, after the barrier layer 50 is formed to protect the sidewall of the groove 40, a protective layer 60a is formed on the surface of the second region 102 exposed at the bottom of the groove 40.

In some embodiments, the protective layer 60a is made of a material including at least one or a combination of more of silicon oxide, silicon nitride, silicon oxynitride, and silicon carbonitride, and polysilicon. In an example embodiment of the present disclosure, the protective layer 60a is made of silicon oxide.

In some embodiments, a method for forming a protective layer 60a may be at least one of the following deposition methods: chemical vapor deposition (CVD), low-pressure chemical vapor deposition (LPCVD), plasma enhanced chemical vapor deposition (PECVD), ultra-high vacuum chemical vapor deposition (UHVCVD), flowable chemical vapor deposition (FCVD), direct liquid injection chemical vapor deposition (DLICVD), rapid thermal chemical vapor deposition (RTCVD), microwave plasma assisted chemical vapor deposition (MPCVD), organometallic chemical vapor deposition (MOCVD), atomic layer deposition (ALD), thermal oxidation growth, wet oxidation growth, and in situ steam generation (ISSG). In an example embodiment of the present disclosure, a wet oxidation growth method is employed for the protective layer 60a. The advantage of wet oxidation is that the silicon on the surface of the second region 102 can be fully oxidized by using water (or water vapor) as an oxidant, while a silicon nitride barrier layer 50 located on the sidewall of the groove 40 is not oxidized or lost at the same time, mainly because the silicon nitride material has a good effect of resisting oxidation and penetration by water vapor.

In some embodiments, the protective layer 60a formed by wet oxygen oxidation extends from the surface of the second region 102 toward the first region 101 by a portion. That is, in addition to oxidizing a silicon material on the surface of the second region 102, at least part of the first region 101 adjacent to the second region 102 is further laterally oxidized. That is, the protective layer 60a is formed on the surface of the second region 102 exposed at the bottom of the groove 40, and is further located on the surface of the region below the barrier layer 50 and on the surface of the region below at least part of the stacked structure 30 close to the groove 40. This has the advantage that at least the second region 102 and part of the first region 101 adjacent to the second region 102 can be fully protected in a subsequent etching process.

In some embodiments, the protective layer 60a formed by wet oxygen oxidation has a thickness ranging from 5 nm to 50 nm.

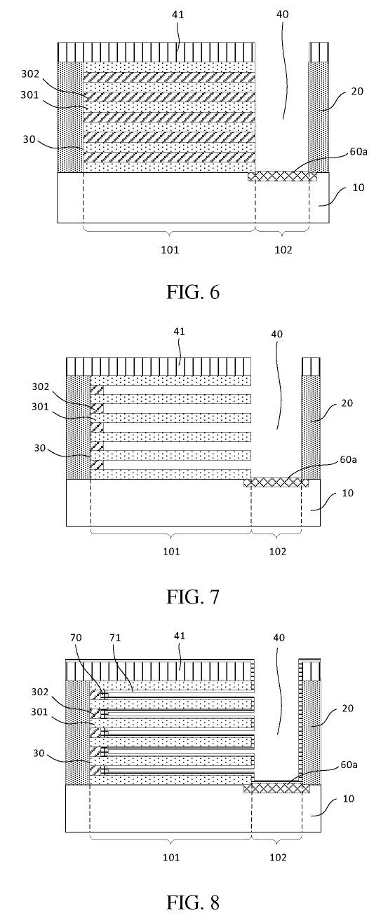

In an example embodiment of the present disclosure, as shown in FIG. 6, after the protective layer 60a is formed, the barrier layer 50 covering the sidewall of the groove 40 is removed to expose the sidewall of the stacked structure 30 close to the groove 40. Specifically, any one or a combination of more of etching methods such as selective plasma dry etching, selective wet etching, reactive ion etching (RIE), and vapor phase chemical etching may be employed, and an etching method with high selectivity does damage the sidewall of the stacked structure 30 exposed by the groove 40.

In an example embodiment of the present disclosure, as shown in FIG. 7, after the protective layer 60a is formed and the groove 40 exposes the sidewall of the stacked structure 30, second etching is performed, and the second material layers 302 in the stacked structure 30 are laterally etched through the groove 40 to remove a part of the second material layers 302. As a part of the second material layers 302 are removed, gaps are formed between the retained first material layers 301.

In some embodiments, any one or a combination of more of etching methods such as selective plasma dry etching, selective wet etching, reactive ion etching (RIE), and vapor phase chemical etching may be employed as an etching method of the second etching. In an example embodiment of the present disclosure, selective wet etching is used as the second etching. Specifically, the second material layers 302 are selectively etched with an ammonia and deionized water mixture (ADM) or tramethylammonium hydroxide (TMAH) as an etching agent.

In the second etching, an etching selection ratio of the protective layer 60a to the second material layers 302 is no more than 1:10. Therefore, due to the existence of the protective layer 60a, at least the surface of the second region 102 exposed at the bottom of the groove 40 and the surface of part of the first region 101 adjacent to the second region 102 are protected, thereby preventing the etching agent in the second etching from damaging the substrate parts of these regions.

In an example embodiment of the present disclosure, after the second etching is performed to remove a part of the second material layers 302, as shown in FIG. 8, a contact material layer 71 is deposited on the surface of the stacked structure, and the contact material layer 71 covers the surface of the first material layer 301 exposed after part of the second material layers 302 are removed, and is in contact with the remaining part of the second material layers 302. Through thermal annealing, a region, which is in contact with the remaining part of the second material layers 302, of the contact material layer 71 is metallized, to form metal-semiconductor contacts as capacitor contact structures 70.

In some embodiments, the contact material layer 71 may be made of any one or more of the following metal materials: cobalt (Co), nickel (Ni), tungsten (W), molybdenum (Mo), titanium (Ti), tantalum (Ta), ruthenium (Ru), and platinum (Pt). Correspondingly, the capacitor contact structures 70 may be made of any one or more of the following metal silicide materials: cobalt silicide (CoSi), nickel silicide (NiSi), tungsten silicide (WSi), molybdenum silicide (MoSi), titanium silicide (TiSi), tantalum silicide (TaSi), ruthenium silicide (RuSi), and platinum silicide (PtSi).

In some embodiments, after the metal semiconductor contacts are formed as the capacitor contact structures 70, the contact material layer 71 that does not participate in a metallization reaction is removed. Specifically, any one or a combination of more of etching methods such as selective plasma dry etching, selective wet etching, reactive ion etching (RIE), and vapor phase chemical etching may be employed.

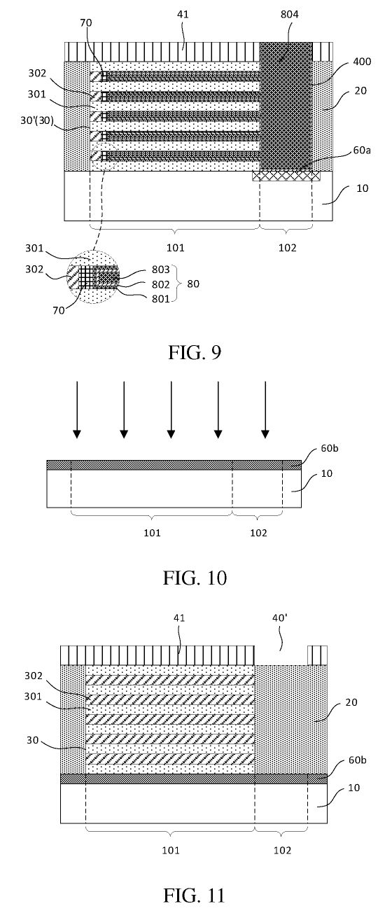

In an example embodiment of the present disclosure, after the metal semiconductor contacts are formed as the capacitor contact structures 70 and the contact material layer 71 that does not participate in a reaction is removed, as shown in FIG. 9, gaps between adjacent first material layers 301 in the stacked structure 30 are filled with a capacitor material through the groove 40 to form capacitor structures 80. Specifically, a first electrode material, a capacitor dielectric material, and a second electrode material are sequentially deposited in each of the gaps between adjacent first material layers 301 through the groove 40 to form a first electrode layer 801, a capacitor dielectric layer 802, and a second electrode layer 803, respectively. As shown in the partially enlarged schematic diagram in FIG. 9, the first electrode layer 801 is in direct contact with the capacitor contact structure 70.

In some embodiments, gaps between adjacent first material layers 301 are each filled with a capacitor structure 80. It should be noted that the first electrode layers 801 of adjacent capacitor structures 80 are disconnected from each other, but the capacitor dielectric layers 802 are connected to each other as a whole, and the second electrode layers 803 are also connected to each other as a whole.

In some embodiments, for the first electrode layers 801 of adjacent capacitor structures 80, after the first electrode material is deposited on the surface of the stacked structure 30, as well as on inner walls of gaps between adjacent first material layers 301, the first electrode material located on the sidewall of the groove 40 is disconnected by an etching method and the first electrode material in other regions is removed through etching, to retain only the first electrode material located on the inner walls of the gaps between the adjacent first material layers 301 in the stacked structure 30 as the first electrode layers 801.

In some embodiments, the capacitor dielectric layers 802 are formed on the surface of the stacked structure 30 and the surfaces of the first electrode layers 801 on the inner walls of the gaps between the adjacent first material layers 301. The capacitor dielectric layers 802 further cover the sidewall and the bottom of the groove 40, namely a top surface of the protective layer 60a.

In some embodiments, the second electrode material is deposited to cover the surfaces of the capacitor dielectric layers 802, and fill the gaps between the adjacent first material layers 301 to form second electrode layers 803. The second electrode material further fills the groove 40 to form a top electrode plate 804, which is configured to connect the second electrode layers 803 into a whole.

In some embodiments, the first electrode layers 801 and the second electrode layers 803 each may be made of at least one or a combination of more of titanium nitride, tantalum nitride, or tungsten nitride, and the capacitor dielectric layers 802 may be made of at least one or a combination of more of silicon oxide (SiO₂), zirconium oxide (ZrO₂), aluminum oxide (Al₂O₃), hafnium oxide (HfO₂), titanium oxide (TiO₂), tantalum oxide (Ta₂O₅), barium strontium titanate (BST), strontium titanate (STO), and lead zirconate titanate (PZT).

In some embodiments, a deposition method for the first electrode layers 801, the capacitor dielectric layers 802, and the second electrode layers 803 may be at least one of the following deposition methods: chemical vapor deposition (CVD), low-pressure chemical vapor deposition (LPCVD), plasma enhanced chemical vapor deposition (PECVD), ultra-high vacuum chemical vapor deposition (UHVCVD), flowable chemical vapor deposition (FCVD), direct liquid injection chemical vapor deposition (DLICVD), rapid thermal chemical vapor deposition (RTCVD), microwave plasma assisted chemical vapor deposition (MPCVD), organometallic chemical vapor deposition (MOCVD), atomic layer deposition (ALD), physical vapor deposition (PVD), and electroplating sputtering.

In another example embodiment of the present disclosure, after the substrate 10 including the first region 101 and the second region 102 is provided in FIG. 1, referring to FIG. 10, ion implantation and annealing are performed on the substrate 10 to form a doped layer on the surface of the second region 102 as a protective layer 60b. In some embodiments, the protective layer 60b is at least further located on the surface of the first region 101. Specifically, ion implantation and annealing may also be performed on the first region 101, or ion implantation may be performed on only the second region 102, and doped ions diffuse from the surface of the second region 102 to the surface of the first region 101 in a subsequent annealing process. In some other embodiments, the protective layer 60b is located on the entire surface of the substrate 10.

In some embodiments, ion implantation and annealing are performed on the substrate 10 with boron ions as doped ions to form a boron doped layer as a protective layer 60b. In some embodiments, the protective layer 60b has a thickness ranging from 20 nm to 40 nm, namely a doping depth ranging from 20 nm to 40 nm. In some embodiments, the concentration of doped elements in the protective layer 60b ranges from 1E+13/cm³ and 1E+21/cm³. It should be noted that the concentration of the doped elements in the protective layer 60b gradually decreases as the depth of extension of the top surface of the substrate 10 toward the interior of the substrate 10 increases.

In some embodiments, as shown in FIG. 11, a stacked structure 30 with multiple first material layers 301 and multiple second material layers 302 alternately stacked is formed on the first region 101.

The first material layers 301 may be made of at least one or any combination of the following materials: silicon oxide, silicon nitride, silicon oxynitride, silicon carbide, silicon carbonitride, and silicon oxycarbonitride. In an example embodiment of the present disclosure, the first material layers 301 are made of silicon oxide. The second material layers 302 may be made of at least one or any combination of the following materials: silicon, germanium, silicon germanium (SiGe), III-V materials, an indium gallium zinc oxide (IGZO), and a two-dimensional material. In an example embodiment of the present disclosure, the second material layers 302 is made of monocrystalline silicon.

In some embodiments, a stacked structure 30 formed by alternately stacking multiple first material layers 301 and multiple second material layers 302 is formed on the first region 101. In some other embodiments, the stacked structure 30 further extends to a region outside the first region 101.

In some embodiments, the structure located in the same horizontal layer as the second material layers 302 alternatively includes insulating material layers and the second material layers 302 that are alternately arranged. The insulating material layers herein may be made of the same material as the first material layers 301. It can be understood that the second material layers 302 in a single horizontal layer are arranged in parallel and at intervals in a strip shape.

In some embodiments, a bottom layer of the stacked structure 30, namely a layer, which is in direct contact with the substrate 10, of the stacked structure 30 is a first material layer 301, to ensure isolation of a subsequently formed capacitor structure or memory cell from the substrate 10. In some embodiments, a top layer of the stacked structure 30, namely a layer, which is farthest from the substrate 10, of the stacked structure 30 is a first material layer 301, to protect the second material layer 302 below the layer and a subsequently formed capacitor structure from possible damage in a subsequent manufacturing process.

In some embodiments, a method for forming a stacked structure 30 includes the steps as follows. An initial stacked structure is first formed on at least a first region 101. Specifically, an initial stacked structure with alternately stacked silicon-silicon germanium (Si-SiGe) is grown on at least the first region 101 by an epitaxial growth method. Then, silicon germanium layers in the initial stacked structure are removed by a method of selective etching. For example, by wet chemical etching with high selectivity, the silicon germanium layer can be sufficiently removed, and silicon layers can be relatively completely retained as second material layers 302. Finally, gaps formed after the removal of the silicon germanium layers are filled with an insulating material as first material layers 301.

In some embodiments, before or after the stacked structure 30 is formed on the first region 101, the method further includes the step as follows. An insulating layer 20 is formed on a region (including at least the second region 102) of the substrate 10 other than the first region 101. The insulating layer 20 is as high as the stacked structure 30.

In some embodiments, after the stacked structure 30 and the insulating layer 20 are formed, the method further includes the step as follows. A mask layer 41 is formed to cover the stacked structure 30 and the insulating layer 20. An opening 40' is formed in the mask layer 41 to expose a top surface of the insulating layer 20 or a part of a top surface of the stacked structure 30. In an example embodiment of the present disclosure, a projection of the opening 40' on the substrate 10 coincides with the second region 102. Specifically, the opening 40' can be formed by a photolithography method to expose a part of the top surface of the insulating layer 20.

In some embodiments, the mask layer 41 may be made of one or a combination of more of a photoresist, a spin-on hardmask (SOH), spin-on carbon (SOC), amorphous carbon, polysilicon, silicon nitride, silicon oxynitride, and silicon carbonitride. In an example embodiment of the present disclosure, the mask layer 41 is made of silicon nitride.

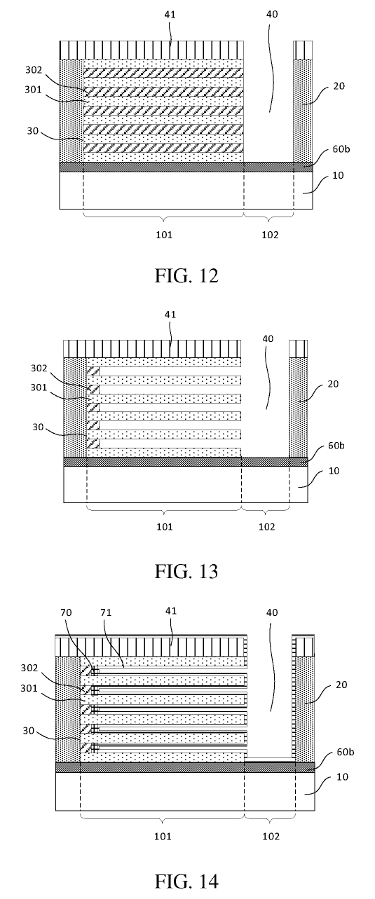

In an example embodiment of the present disclosure, in an example in which the first region 101 is adjacent to the second region 102 (namely in the case of (a) in FIG. 1), after the mask layer 41 with the opening 40' is formed as shown in FIG. 11, referring to FIG. 12, first etching is performed. That is, the insulating layer 20 in contact with one end of the stacked structure 30 is etched through the opening 40' to form a groove 40. A surface of the second region 102, namely a surface of the protective layer 60b formed on the surface of the second region 102, is exposed at the bottom of the groove 40, and at least one end of each of all the second material layers 302 in the stacked structure 30 is exposed from a sidewall of the groove 40.

In another example embodiment of the present disclosure, in an example in which the first region 101 and the second region 102 partially overlap (namely in the case of (b) in FIG. 1), after the mask layer 41 with the opening 40' is formed, the opening 40' further exposes part of the top surface of the stacked structure 30, and first etching is performed. That is, the insulating layer 20 in contact with one end of the stacked structure 30 and the exposed part of the stacked structure 30 are etched through the opening 40' to form a groove 40. A surface of the second region 102, namely a surface of the protective layer 60b formed on the surface of the second region 102, is exposed at the bottom of the groove 40, and at least one end of each of all the second material layers 302 in the stacked structure 30 is exposed from a sidewall of the groove 40.

In still another example embodiment of the present disclosure, in an example in which the second region 102 is entirely located in the first region 101 (namely in the case of (b) in FIG. 1), after the mask layer 41 with the opening 40' is formed, the opening 40' exposes only a part of the top surface of the stacked structure 30, and first etching is performed. That is, the exposed part of the stacked structure 30 is etched through the opening 40' to form a groove 40. A surface of the second region 102, namely a surface of the protective layer 60b formed on the surface of the second region 102, is exposed at the bottom of the groove 40, and at least one end of each of all the second material layers 302 in the stacked structure 30 is exposed by a sidewall of the groove 40.

In some embodiments, an etching method of the first etching may be at least one of the following deposition methods: plasma dry etching, ion beam etching (IBE), and reactive ion etching (RIE).

In some embodiments, after the first etching is performed to form the groove 40, the mask layer 41 remains at least at the top of the stacked structure 30. In some other embodiments, the mask layer 41 is removed in a subsequent process.

In an example embodiment of the present disclosure, after the groove 40 is formed to expose the sidewall of the stacked structure 30 and the top surface of the protective layer 60b located on the second region 102, second etching is performed. As shown in FIG. 13, the second material layers 302 in the stacked structure 30 are laterally etched through the groove 40 to remove a part of the second material layers 302. As a part of the second material layers 302 are removed, gaps are formed between the retained first material layers 301.

In some embodiments, any one or a combination of more of etching methods such as selective plasma dry etching, selective wet etching, reactive ion etching (RIE), and vapor phase chemical etching may be employed as an etching method of the second etching. In an example embodiment of the present disclosure, selective wet etching is used as the second etching. Specifically, the second material layers 302 are selectively etched with an ammonia and deionized water mixture (ADM) or tramethylammonium hydroxide (TMAH) as an etching agent.

In the second etching, an etching selection ratio of the protective layer 60b to the second material layers 302 is no more than 1:10. Therefore, due to the existence of the protective layer 60b, at least the surface of the second region 102 exposed at the bottom of the groove 40 and the surface of part of the first region 101 adjacent to the second region 102 are protected, thereby preventing the etching agent in the second etching from damaging the substrate parts of these regions.

In an example embodiment of the present disclosure, after the second etching is performed to remove a part of the second material layers 302, as shown in FIG. 14, a contact material layer 71 is deposited on the surface of the stacked structure, and the contact material layer 71 covers the surface of the first material layer 301 exposed after part of the second material layers 302 are removed, and is in contact with the remaining part of the second material layers 302. Through thermal annealing, a region, which is in contact with the remaining part of the second material layers 302, of the contact material layer 71 is metallized, to form metal-semiconductor contacts as capacitor contact structures 70.

In some embodiments, the contact material layer 71 may be made of any one or more of the following metal materials: cobalt (Co), nickel (Ni), tungsten (W), molybdenum (Mo), titanium (Ti), tantalum (Ta), ruthenium (Ru), and platinum (Pt). Correspondingly, the capacitor contact structures 70 may be made of any one or more of the following metal silicide materials: cobalt silicide (CoSi), nickel silicide (NiSi), tungsten silicide (WSi), molybdenum silicide (MoSi), titanium silicide (TiSi), tantalum silicide (TaSi), ruthenium silicide (RuSi), and platinum silicide (PtSi).

In some embodiments, after the metal semiconductor contacts are formed as the capacitor contact structures 70, the contact material layer 71 that does not participate in a metallization reaction is removed. Specifically, any one or a combination of more of etching methods such as selective plasma dry etching, selective wet etching, reactive ion etching (RIE), and vapor phase chemical etching may be employed.

In an example embodiment of the present disclosure, after the metal semiconductor contacts are formed as the capacitor contact structures 70 and the contact material layer 71 that does not participate in a reaction is removed, as shown in FIG. 15, gaps between adjacent first material layers 301 in the stacked structure 30 are filled with a capacitor material through the groove 40 to form capacitor structures 80, so as to form a new stacked structure 30'. Specifically, a first electrode material, a capacitor dielectric material, and a second electrode material are sequentially deposited in each of the gaps between adjacent first material layers 301 through the groove 40 to form a first electrode layer 801, a capacitor dielectric layer 802, and a second electrode layer 803, respectively. As shown in the partially enlarged schematic diagram in FIG. 15, the first electrode layer 801 is in direct contact with the capacitor contact structure 70.

In some embodiments, gaps between adjacent first material layers 301 are each filled with a capacitor structure 80. It should be noted that the first electrode layers 801 of adjacent capacitor structures 80 are disconnected from each other, but the capacitor dielectric layers 802 are connected to each other as a whole, and the second electrode layers 803 are also connected to each other as a whole.

In some embodiments, for the first electrode layers 801 of adjacent capacitor structures 80, after the first electrode material is deposited on the surface of the stacked structure 30, as well as on inner walls of gaps between adjacent first material layers 301, the first electrode material located on the sidewall of the groove 40 is disconnected by an etching method and the first electrode material in other regions is removed through etching, to retain only the first electrode material located on the inner walls of the gaps between the adjacent first material layers 301 in the stacked structure 30 as the first electrode layers 801.

In some embodiments, the capacitor dielectric layers 802 are formed on the surface of the stacked structure 30 and the surfaces of the first electrode layers 801 on the inner walls of the gaps between the adjacent first material layers 301. The capacitor dielectric layers 802 further cover the sidewall and the bottom of the groove 40, namely a top surface of the protective layer 60b.

In some embodiments, the second electrode material is deposited to cover the surfaces of the capacitor dielectric layers 802, and fill the gaps between the adjacent first material layers 301 to form second electrode layers 803. The second electrode material further fills the groove 40 to form a top electrode plate 804, which is configured to connect the second electrode layers 803 into a whole.

In some embodiments, the first electrode layers 801 and the second electrode layers 803 each may be made of at least one or a combination of more of titanium nitride, tantalum nitride, or tungsten nitride, and the capacitor dielectric layers 802 may be made of at least one or a combination of more of silicon oxide (SiO₂), zirconium oxide (ZrO₂), aluminum oxide (Al₂O₃), hafnium oxide (HfO₂), titanium oxide (TiO₂), tantalum oxide (Ta₂O₅), barium strontium titanate (BST), strontium titanate (STO), and lead zirconate titanate (PZT).

In some embodiments, a deposition method for the first electrode layers 801, the capacitor dielectric layers 802, and the second electrode layers 803 may be at least one of the following deposition methods: chemical vapor deposition (CVD), low-pressure chemical vapor deposition (LPCVD), plasma enhanced chemical vapor deposition (PECVD), ultra-high vacuum chemical vapor deposition (UHVCVD), flowable chemical vapor deposition (FCVD), direct liquid injection chemical vapor deposition (DLICVD), rapid thermal chemical vapor deposition (RTCVD), microwave plasma assisted chemical vapor deposition (MPCVD), organometallic chemical vapor deposition (MOCVD), atomic layer deposition (ALD), physical vapor deposition (PVD), and electroplating sputtering.

In some embodiments, the structure located in the same horizontal layer as the capacitor structures 80 alternatively includes insulating material layers and the capacitor structures 80 that are alternately arranged. The insulating material layers herein may be made of the same material as the first material layers 301. It can be understood that the capacitor structures 80 in a single horizontal layer are arranged in parallel and at intervals in a strip shape. FIG. 16 is a schematic cross-sectional view taken along line A-A' of FIG. 15. Multiple capacitor structures 80 are arranged in an array in the stacked structure 30.

In the method for manufacturing a semiconductor structure according to the present disclosure, on the one hand, the protective layer is formed on the substrate surface at the bottom of the groove and a nearby region, so that the substrate surface at the bottom of the groove and the nearby region can be effectively protected when sacrificial materials (part of the second material layers 302) are etched laterally. This avoids the formation of cavities caused by etching by an etching agent in related technologies, thereby avoiding instability and uncertainty in the subsequent process flow. On the other hand, there is low difficulty and high feasibility in implementing the process steps of forming the protective layer, and a structure with high device reliability can be obtained without increasing too many costs.

Based on the method for manufacturing a semiconductor structure, the present disclosure further provides a semiconductor structure. As shown in FIG. 9 or FIG. 15, the semiconductor structure includes at least a substrate 10, where the substrate 10 includes a first region 101 and a second region 102; a stacked structure 30' located on the first region 101; a trench structure 400 located at one end of the stacked structure 30' and located on the second region 102; and a protective layer 60a or 60b located on a surface of the second region 102 and at the bottom of the trench structure 400. The protective layer 60a or 60b further extends at least toward a surface of the first region 101.

In an example embodiment of the present disclosure, referring to FIG. 9, the protective layer 60a is a wet oxygen layer, namely an oxide layer formed by wet oxygen oxidation. In some embodiments, the protective layer 60a formed by wet oxygen oxidation has a thickness ranging from 5 nm to 50 nm.

In another example embodiment of the present disclosure, referring to FIG. 15, the protective layer 60b is a boron doped layer. In some embodiments, the boron doped layer has a doping depth of 20 nm to 40 nm. That is, the protective layer 60b has a thickness ranging from 20 nm to 40 nm. In some embodiments, the concentration of doped elements in the protective layer 60b ranges from 1E+13/cm³ and 1E+21/cm³. It should be noted that the concentration of the doped elements in the protective layer 60b gradually decreases as the depth of extension of the surface of the substrate 10 toward the interior of the substrate 10 increases.

In some embodiments, the first region 101 is adjacent to the second region 102, and specifically, reference may be made to the case of (a) in FIG. 1. In some other embodiments, the first region 101 and the second region 102 partially overlap, and specifically, reference may be made to the case of (b) in FIG. 1. In still some other embodiments, the second region 102 is entirely located in the first region 101, and specifically, reference may be made to the case of (c) in FIG. 1.

In some embodiments, the trench structure 400 includes a top electrode plate 804 formed through filling with a second electrode material, and a surface (including a bottom surface and a sidewall) of an inner wall of the trench structure 400 is further covered with a capacitor dielectric layer 802. In some embodiments, the electrode material may be at least one or a combination of more of titanium nitride, tantalum nitride, or tungsten nitride.

In some embodiments, the stacked structure 30' includes a stack of multiple capacitor structures 80 and isolation structures. Each of the isolation structures includes multiple first material layers 301 and insulating material layers alternately arranged in the same horizontal layer structure with the capacitor structures 80. The isolation structures are located between adjacent capacitor structures 80 and separate the adjacent capacitor structures 80. In some embodiments, the insulating material layers and the first material layers 301 may be made of the same material. In an example embodiment of the present disclosure, the first material layers 301 and the insulating material layers each are made of silicon oxide.

In some embodiments, the stacked structure 30' further includes active structures (namely the remaining second material layers 302 in the stacked structure 30) and capacitor contact structures 70. The active structures each are located at one end of one capacitor structure 80 away from the trench structure 400, correspond to the capacitor structures 80 one to one, and are configured as a source and a drain of a transistor and a channel region between the source and the drain. The capacitor contact structures 70 are located between the active structures and the capacitor structures 80, and the active structures are connected to the capacitor structures 80 through the capacitor contact structures 70.

In some embodiments, the active structures may be made of at least one or any combination of the following materials: silicon, germanium, silicon germanium (SiGe), III-V materials, an indium gallium zinc oxide (IGZO), and a two-dimensional material. In an example embodiment of the present disclosure, the active structures are made of doped monocrystalline silicon.

In some embodiments, the capacitor contact structures 70 may be made of any one or more of the following metal silicide materials: cobalt silicide (CoSi), nickel silicide (NiSi), tungsten silicide (WSi), molybdenum silicide (MoSi), titanium silicide (TiSi), tantalum silicide (TaSi), ruthenium silicide (RuSi), and platinum silicide (PtSi).

In an example embodiment of the present disclosure, the semiconductor structure according to the present disclosure further includes word line structures 91a and bit line structures 92a. As shown in FIG. 17A, the word line structures 91a penetrate through the stacked structure 30', are connected to vertically arranged active structures in the same column, and are configured to control turn-on or turn-off of memory transistors in this column. The bit line structures 92a are each located at one end of one active structure away from one capacitor structure 80, are connected to horizontally arranged active structures in the same row, and are configured to provide or sense stored charges in memory capacitors in this row.

In another example embodiment of the present disclosure, the semiconductor structure according to the present disclosure further includes word line structures 91b and bit line structures 92b. As shown in FIG. 17B, the word line structures 91b are connected to horizontally arranged active structures in the same row, and are configured to control turn-on or turn-off of memory transistors in this row. The bit line structures 92b penetrate through the stacked structure 30', are each located at one end of one active structure away from one capacitor structure 80, are connected to vertically arranged active structures in the same column, and are configured to provide or sense stored charges in memory capacitors in this column.

In some embodiments, the steps of forming the word line structures 91a or 91b and the bit lines structure 92a or 92b may be before the above-mentioned step of forming the capacitor structures 80. That is, before the groove 40 is formed, the word line structures 91a or 91b and/or the bit line structures 92a or 92b have been formed at the other end of the stacked structure 30. In some other embodiments, the step of forming the word line structures 91a or 91b and the bit lines structure 92a or 92b may be after the above-mentioned step of forming the capacitor structures 80. That is, after the top electrode plate 804 is formed to fill the groove 40, the word line structures 91a or 91b and/or the bit line structures 92a or 92b are formed at the other end of the stacked structure 30'.

The semiconductor structure according to the present disclosure includes the protective layer on the substrate surface at the bottom of the groove and the nearby region. This solves the problems in the related technologies that a substrate surface at the bottom of a groove is eroded to form cavities during lateral etching of a sacrificial layer in a stacked structure, and a related device manufactured from the semiconductor structure has good device reliability.

It should be noted that the semiconductor structure according to the embodiment of the present disclosure may be configured to manufacture a 3D DRAM device, or may be configured to manufacture a 3D device in which a sacrificial layer in a stacked structure needs to be laterally etched. There are no too many restrictions herein.

Various semiconductor structures shown in this specific implementation may be configured for an electronic device having a memory function. The electronic device may be a terminal device, e.g., a mobile phone, a tablet computer, or a smart bracelet, or may be a personal computer (personal computer, PC), a server, a workstation, or the like. The memory function of the electronic device may be implemented by the following memories: a dynamic random access memory (DRAM), a ferroelectric random access memory (FRAM), a phase change memory (PCM), a magnetic random access memory (MRAM), or a resistive random access memory (RRAM).

The foregoing descriptions are merely specific implementations of the present disclosure, but are not intended to limit the protection scope of the present disclosure. Any variation or replacement readily figured out by a person skilled in the art within the technical scope disclosed in the present disclosure shall fall within the protection scope of the present disclosure. Therefore, the protection scope of the present disclosure shall be subject to the protection scope of the claims.

What is claimed is:

1. A method for manufacturing a semiconductor structure, comprising:
providing a substrate, the substrate comprising a first region and a second region;
forming, on the first region, a stacked structure with a plurality of first material layers and a plurality of second material layers alternately stacked;
performing first etching to form a groove at one end of the stacked structure, the second region being exposed at a bottom of the groove; and
performing second etching, to remove a part of the plurality of second material layers through the groove, and retain the plurality of first material layers arranged at intervals,
before the performing second etching, the method further comprising forming a protective layer on a surface of the second region, the protective layer further extending toward at least a surface of the first region.

2. The method for manufacturing a semiconductor structure according to claim 1, wherein the protective layer is formed after the first etching is performed, comprising:
oxidizing the second region exposed at the bottom of the groove, to form an oxide layer on the surface of the second region as the protective layer.

3. The method for manufacturing a semiconductor structure according to claim 2, wherein an oxidation mode is wet oxidation.

4. The method for manufacturing a semiconductor structure according to claim 2, before the oxidizing the second region exposed at the bottom of the groove, further comprising forming a barrier layer on a sidewall of the groove; and
after the forming an oxide layer on the surface of the second region as the protective layer, further comprising: removing the barrier layer.

5. The method for manufacturing a semiconductor structure according to claim 1, wherein the protective layer is formed before the stacked structure is formed, comprising:
performing ion implantation and annealing on a surface of the substrate, to form a doped layer on the surface of the second region as the protective layer.

6. The method for manufacturing a semiconductor structure according to claim 5, wherein the ion implantation is performed by boron ions.

7. The method for manufacturing a semiconductor structure according to claim 5, wherein the doped layer is further located on the surface of the first region.

8. The method for manufacturing a semiconductor structure according to claim 1, after the performing second etching, to remove a part of the plurality of second material layers through the groove, and retain the plurality of first material layers arranged at intervals, the method further comprising:
filling gaps between the plurality of first material layers with a capacitor material through the groove to form a capacitor structure, the capacitor structure comprising a first electrode layer, a capacitor dielectric layer, and a second electrode layer that are sequentially stacked.

9. The method for manufacturing a semiconductor structure according to claim 8, before the filling with the capacitor material, the method further comprising: metallizing the plurality of second material layers retained after the second etching to form a capacitor contact structure.

10. A semiconductor structure, comprising:
a substrate, the substrate comprising a first region and a second region;
a stacked structure located on the first region;
a trench structure located at one end of the stacked structure and located on the second region; and
a protective layer located on a surface of the second region and at a bottom of the trench structure, and further extending toward at least a surface of the first region.

11. The semiconductor structure according to claim 10, wherein the protective layer is a wet oxygen layer or a boron doped layer.

12. The semiconductor structure according to claim 10, wherein the first region and the second region are adjacent or at least partially overlap.

13. The semiconductor structure according to claim 10, wherein the trench structure comprises a top electrode plate formed through filling with a second electrode material.

14. The semiconductor structure according to claim 10, wherein the stacked structure comprises a plurality of capacitor structures and isolation structures that are alternately stacked, and the isolation structures are located between adjacent capacitor structures.

15. The semiconductor structure according to claim 14, wherein the stacked structure further comprises:
active structures located at one end of each of the capacitor structures away from the trench structure and corresponding to the capacitor structures one to one; and
capacitor contact structures located between the active structures and the capacitor structures, the active structures being connected to the capacitor structures through the capacitor contact structures.
